(19) United States
(12) Patent Application Publication
(10) Pub. No.: US 2009/0044744 A1
(43) Pub. Date: Feb. 19, 2009

(54) Thermal Sensitive Material

(75) Inventors: Bryan E. Koene, Blacksburg, VA (US); James D. Oxley, San Antonio, TX (US); Jonas C. Gunter, Blacksburg, VA (US)

Correspondence Address: JOY L BRYANT, P.C., P O BOX 620, LIGHTFOOT, VA, 23090-0620, US

(73) Assignees: LUNA INNOVATIONS INCORPORATED, Roanoke, VA (US); SOUTHWEST RESEARCH INSTITUTE, San Antonio, TX (US)

(21) Appl. No.: 12/021,451

(22) Filed: Jan. 29, 2008

Related U.S. Application Data
(60) Provisional application No. 60/887,172, filed on Jan. 30, 2007.

(51) Int. Cl. G01D 21/00; C08L 23/06; C08L 23/12; C08G 63/00; C08L 25/06; H05K 1/02; C08G 73/10; C08L 23/00; C09D 7/12

(52) U.S. Cl. 116/207; 524/585; 524/582; 524/599; 524/577; 524/612; 524/570; 252/600; 252/301.21; 252/301.16; 106/287.35; 174/256

(57) ABSTRACT

An impact-resistant thermal sensitive material comprising at least one indicator dispersed throughout a heat-sensitive matrix material is provided. An article comprising the impact-resistant thermal sensitive material undergoes a permanent color change when exposed to a pre-determined temperature.

### CROSS-REFERENCE TO RELATED APPLICATIONS

This application claims the benefit of U.S. Provisional Patent Application Ser. No. 60/887,172, entitled, “Thermal Sensitive Material,” filed Jan. 30, 2007, which is hereby incorporated by reference in its entirety.

### STATEMENT REGARDING FEDERALLY SPONSORED RESEARCH OR DEVELOPMENT

The U.S. Government has a paid-up license in this invention and the right in limited circumstances to require the patent owner to license others on reasonable terms as provided for by the terms of Contract No. N68335-06-C-0291 awarded by the United States Navy, Naval Air Warfare Center.

### FIELD OF THE INVENTION

The present invention is related to materials and coatings capable of indicating when exposure to various temperatures has occurred. In particular, it is related to a material comprising an indicator which is dispersed throughout a heat-sensitive matrix.

### BACKGROUND OF THE INVENTION

When a structural component is suspected of having undergone some type of thermal exposure, it is necessary to evaluate the component to determine where the exposure has occurred, whether or not the component has been damaged, and the extent of the damage. Typically, non-destructive evaluation techniques such as x-ray microscopy, scanning acoustic microscopy (SAM), environmental scanning electron microscopy (E-SEM), energy dispersive spectrometry (EDS), infrared imaging, fiber optics, and other spectroscopic techniques are used to evaluate and determine whether there was any damage done to the structure component or material. However, these techniques require complete removal or detachment of the component from the structure in order to be evaluated. Hence, it is difficult to determine the specific points of damage and evaluation times are quite lengthy. Rather, it is desirable to have a method for determining whether thermal damage has occurred by visual inspection.

Various temperature indicating materials have been disclosed. Barrett in U.S. Pat. No. 5,340,537 describes temperature indicating compositions of dispersions in an aqueous binder of a color changing electron donating compound having a specific melting point and a polymeric electron accepting resin that reacts with the electron donating compound to produce a visible and permanent color change. Such compounds have a glass transition temperature (T_{g}) and non-volatility effective to provide a color change to coatings containing the composition upon exposure to a predetermined heat history. One problem with these types of compounds is that they have a tendency to undergo a premature color change due to a lack of environmental stability. Barrett proposes to solve this problem by providing a dispersion of a color changing electron donating compound (chromogen or prodye) having a melting point greater than 300° F. and a polymeric electron accepting resin reactive with the electron donating compound both of which are contained in an aqueous binder. Neither the polymeric electron accepting resin nor the prodye or chromogen electron donating compound are encapsulated in microcapsules. It is taught that non-encapsulation leads to an improvement in product cost and production efficiency. However, the final products are limited to coatings and films and the compound cannot be used to make articles and structural components.

An object of the present invention is to provide a thermal sensitive material that, when incorporated into a finished product, identifies whether exposure to a particular temperature has occurred.

### SUMMARY OF THE INVENTION

By the present invention, a thermal sensitive material is provided. By thermal sensitive, it is meant that the material is capable of manifesting a permanent color change when exposed to a pre-determined temperature range. The thermal sensitive material comprises at least one indicator dispersed throughout a heat-sensitive matrix material. By heat-sensitive it is meant that the material either undergoes thermal melting, thermal degradation, or goes through its glass transition state upon exposure to a particular temperature range. The resulting thermal sensitive material is impact-resistant. By impact-resistant, it is meant that the indication will not be manifested through mechanical means such as scratches, abrasion, cutting, impacts, bending, or other mechanical perturbation of the object. The thermal sensitive material is used in preparing articles capable of showing when they have been exposed to certain pre-determined temperatures. Such articles include but are not limited to: polymeric containers, circuit boards, and electronic devices as well as films, coatings, appliques, and other shaped articles.

Additional objects and advantages of the invention will be set forth in part in the description which follows, and in part, will be obvious from the description, or may be learned by practice of the invention. The objects and advantages of the invention will be obtained by means of instrumentalities in combinations particularly pointed out in the appended claims.

### BRIEF DESCRIPTION OF THE DRAWINGS

The accompanying drawings illustrate a complete embodiment of the invention according to the best modes so far devised for the practical application of the principles thereof, and in which:

FIG. 1 depicts one embodiment of the thermal sensitive material of the present invention wherein an indicator is dispersed throughout a heat-sensitive matrix material.

FIG. 2 depicts an alternate embodiment of the thermal sensitive material of the present invention wherein a dye material is dispersed throughout a first heat-sensitive matrix material, forming a core which is surrounded by an activator dispersed throughout a second heat-sensitive matrix material.

### DETAILED DESCRIPTION OF THE PREFERRED EMBODIMENTS

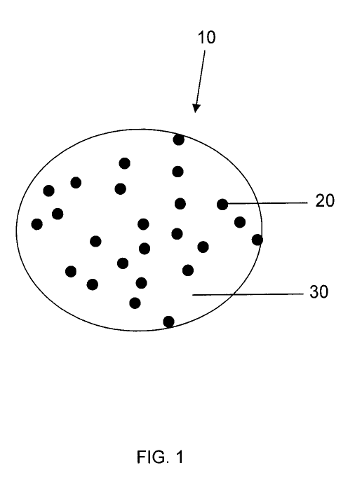

Referring now to the drawings where similar elements are numbered the same throughout the specification, FIG. 1 depicts the simplest embodiment of the thermal sensitive material 10 of the present invention. Although the drawing depicts the thermal sensitive material 10 as having an oval shape, this is for illustration only and it should be noted that the thermal sensitive material may be of any shape suitable for a particular application. In particular, the thermal sensitive material 10 is formed into an article and preferably, the article is selected from the group consisting of: a coating; a film; a paint; a decal; an applique; and a shaped article. Most preferably, the shaped article is a polymeric container; a circuit board; and an electronic device. In its simplest embodiment, the thermal sensitive material 10 comprises at least one indicator 20 dispersed throughout a heat-sensitive matrix material 30. Once formed, the thermal sensitive material is impact-resistant. Impact-resistance is necessary in order to prevent premature release of the indicator to the surrounding environment.

In a preferred embodiment, the indicator 20 which is dispersed throughout the heat-sensitive matrix material 30 is chemically the same (meaning only one type of indicator). In an alternate embodiment, a plurality of different kinds of indicators are dispersed throughout the heat-sensitive material. Any indicator known to indicate a thermal change may be used in the present invention. Preferably, the indicator is a dye or metal oxide pigment and most preferably, the dye or metal oxide pigment is a reactive dye or metal oxide pigment that causes a permanent color change in the article when the dye is exposed to a specific environment. Examples of the specific environment include but are not limited to: heat, air, visible light, ultraviolet light, black light, ultraviolet radiation, infra-red radiation, microwave radiation, x-rays, water, and acoustic radiation. In particular, the specific environment is a chemical environment comprising at least one activator.

More preferably, the indicator is a system comprising a reactive dye or metal oxide pigment known to undergo an oxidation process to achieve a color change. These materials may be an electron donor which manifests itself when exposed to an activator known to be an electron acceptor or redox materials (in the case of metal oxide pigments) which oxidize at elevated temperatures in the presence of air. Examples of various reactive dyes which are electron donors include but are not limited to: a fluorescent dye; a leuco dye (commercially available from Ciba); a pH-sensitive dye such as quinine, fluorescein, umbelliferone, and calcein (commercially available from Aldrich); an optical brightener (such as umbelliferone); and a fluorescent brightener (such as Uvitex or Tanopal which are commercially available from Ciba). Various activators include acid donating or electron accepting substances such as acids having pKas less than that of the reactive dye or a Lewis acid. One such example is zinc salicylate. Alternative activators include but are not limited to: phenols; substituted phenols; solid acids; and polymeric acids. When the reactive dye/activator system is employed, the reactive dye is typically dispersed throughout the heat-sensitive matrix material and the activator is present in an external chemical environment. Conversely, the activator is dispersed throughout the heat-sensitive matrix material and the reactive dye is present in an external chemical environment. By external chemical environment, it is meant an environment comprised of at least one polymer. An example of such an environment is a coating. In the systems where metal oxide pigments are used as an indicator, the metal oxide pigments are typically transition metal oxides or sulfides, which undergo color changes through different oxidation states when exposed to elevated temperatures in air. Examples of these pigments include but are not limited to: iron oxide, vanadium oxide, and lead oxide. The use of such pigments enable thermal detection at temperatures up to 600° C.

The indicator 20 is dispersed throughout a heat-sensitive matrix material 30. By heat-sensitive it is meant that the matrix material is capable of undergoing a change in its physical state. For example, the matrix material passes through its glass transition state (T_{g}) at a certain temperature range; degrades (T_{d}) at a certain temperature range; or melts (Tₘ) at a certain temperature range. Any of these changes is suitable and necessary for the present invention to work. As the matrix material is exposed to various temperature ranges, thus affecting its T_{g}, T_{d}, or Tₘ, the matrix material allows; the suspended indicator to migrate out of the matrix material and thus manifest itself in the exposed area as a permanent color change. Preferably, the temperature range at which the matrix material undergoes a change in its physical state ranges from about 100° C. to about 450° C. The heat-sensitive matrix material is any material capable of undergoing a change in its physical state, able to allow for dispersion of an indicator material throughout, and is preferably one that is impact-resistant at room temperature. Examples of these matrix materials include natural and synthetic polymers. Most preferably, the matrix material is a wax. Alternatively, preferred synthetic polymers include but are not limited to: polyethylene, polypropylene, cellulose acetate, polyester, polystyrene, polyamide, polycarbonate, polyolefin, fluoropolymer, polyvinyl chloride, and polyimide polymers. The heat-sensitive matrix material does not need to be limited to a particular homopolymer but may also be comprised of a polymer blend having separate or different T_{g}, T_{d}, or Tₘ. Such a blend would be desirable when one is trying to detect thermal changes or a range of specific temperatures. Selection of the matrix material is based on the temperature range at which one desires to detect thermal exposure.

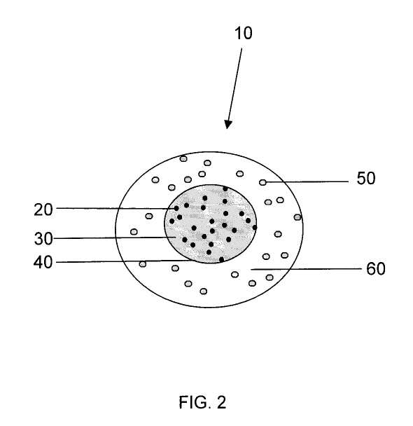

In another embodiment of the invention, depicted in FIG. 2, the thermal sensitive material 10 comprises at least one dye material 20 dispersed throughout a first heat-sensitive matrix material 30 forming a core 40 surrounded by an activator 50 dispersed throughout a second heat-sensitive matrix material 60. The composition of the first heat-sensitive matrix material may be the same or different from the second heat-sensitive matrix material depending on the final application. As the thermal sensitive material is exposed to a temperature affecting either the T_{g}, T_{d}, or Tₘ of the first and/or second heat-sensitive matrix material, the activator and dye will come into contact, react, and cause a permanent color change in the thermal sensitive material when the heat-sensitive matrix materials experience a change in their physical states. In those cases where the T_{g}, T_{d}, or Tₘ of the second heat-sensitive matrix material is lower than that of the first heat-sensitive matrix material, only one component (the activator) is released to the environment and no reaction will take place until the T_{g}, T_{d}, or Tₘ, for the first heat-sensitive matrix material is realized and, therefore, no permanent color change will occur initially or until the second temperature range is reached.

It should be noted here that it is important that the thermal sensitive material be impact-resistant. If the thermal sensitive material is not impact-resistant, the indicator may be released to the surrounding environment prior to experiencing exposure to a temperature change. Rather, the focus of this invention is to provide a thermal sensitive material that is used to indicate exposure to a particular temperature by manifesting a permanent color change in the material. Moreover, due to the impact-resistant nature of the material coupled with the thermoplastic heat-sensitive matrix material used, the indicator is protected from adverse environmental conditions such as temperatures below the T_{g}, T_{d}, or Tₘ of the matrix material as well as impact, moisture, and other conditions that may result in premature manifestation of a color change.

The thermal sensitive material of the present invention is used to prepare articles such as coatings, films, paints, decals, appliques, and shaped articles. More specifically, the shaped articles, include but are not limited to: polymeric containers, circuit boards, and electronic devices. The thermal sensitive material is formed into any shape suitable for the final application. Preferably, the thermal sensitive material is part of a coating for an underlying substrate. In this application, the thermal sensitive material (coating) is applied to a substrate such as: mechanical equipment, structural components, containers, or electronic equipment and is used to indicate when the substrate has been exposed to a particular temperature or range of temperatures. When the thermal sensitive material is incorporated into a coating, the thermal sensitive material is a particle having a diameter ranging from about 100 nm to about 1 mm and, more preferably, about 5 μm to about 50 μm. Because of the thermal sensitive nature of the material, articles which incorporate the thermal sensitive material must be fabricated at temperatures below the T_{g}, Tₘ, and T_{d} of the heat-sensitive matrix materials.

The thermal sensitive material of the present invention is used to detect whether an article has been exposed to a pre-determined temperature. In practicing this method, the thermal sensitive material is incorporated into the fabrication of an article either directly by formulating the material into the article or indirectly by first fabricating a coating or film containing the material and then applying the coating or film to an article. As the article is exposed to a temperature falling within the T_{g}, Tₘ, or T_{d} of the thermal sensitive material, the heat-sensitive matrix material releases the indicator to the surrounding environment and a permanent color change is activated either by way of heat, air, visible light, ultraviolet light, black light, ultraviolet radiation, infra-red radiation, microwave radiation, x-ray, water and/or acoustic radiation. Alternatively, if a two-part dye/activator system is used, a permanent color change will occur when the dye contacts the activator. When this is the case, the indicator (dye) has been exposed to a chemical environment comprising at least one activator. The color change is detected either visually or spectroscopically.

Exposure to a range of temperatures is detectable when a plurality of thermal sensitive materials, are incorporated into an article. In this case, the T_{g}, Tₘ, or Tⱼ of the heat-sensitive matrix material for each thermal sensitive material is different and the indicator within each material is also different. Upon exposure to a temperature within the range of the T_{g}, Tₘ, or T_{d} of a particular thermal sensitive material, only the indicator from that material is exposed and based on the color change, one is able to determine what temperature or temperatures the article was exposed to. For example, an airplane wing comprising a first thermal sensitive material and a second thermal sensitive material is prepared. The first thermal sensitive material comprises an indicator of red dye and a heat-sensitive matrix material of wax which melts at 100° C. The second thermal sensitive material comprises an indicator of blue dye and a heat-sensitive matrix material of cellulose acetate which melts at 250° C. As the airplane wing is exposed to temperatures of 100° C., the red dye becomes visible. One is able to see that an exposure above 100° C. but less than 250° C. has occurred. This enables the maintenance person to take the necessary action to rectify any damage that may have occurred from such an exposure. Since the thermal sensitive material is impact-resistant, the maintenance person is able to rule-out that the exposure was a result of impact damage.

### EXAMPLES

### Example 1

Thermal sensitive materials were prepared using a rotating disc atomization technique. A solution of dichloromethane with 2% solids was prepared with a 20:1 ratio of cellulose acetate butyrate (molecular weight 12,000; commercially available from Aldrich) and a leuco dye (Pergascript Red commercially available from Ciba). The solution was added at 30 g/min to a 4 inch diameter rotating disc spinning at 4000 rpm. The resulting thermal sensitive materials were in the form of particles formed off the disc and were collected in a 3 foot diameter plastic cone and funneled through a small cyclone for isolation. The thermal sensitive materials had the following properties:

Median particle size: 27.2 μm
Melting point: 200° C.

### Example 2

Thermal sensitive materials in the shape of beads were prepared from polyethylene (commercially available from Aldrich) having the molecular weights of 500, 3000, and 12,000 using an emulsion chilling process. Each polymer was melted in the presence of a leuco dye (known as Pergascript Red I-6B commercially available from Ciba) at a ratio of 20:1 polymer to dye to form a homogeneous solution. The liquid solution was emulsified into a bath of hot (150° C.) glycerin or silicon oil and rapidly chilled (25° C.) to form solid beads of polymer and dye. Beads formed in the glycerin bath were isolated, through dilution of the glycerin with water, filtration, and subsequent washes with water. Beads formed in the silicon oil were isolated using a similar method with acetone substituted for water as the dilution and rinsing solvent. The resulting beads had the following properties:

| Molecular Weight | | |
|---|---|---|
| (Polyethylene) | Particle Size (nm) | Melting Point |
| 500 | 38.8 | 75° C. |
| 3,000 | 36.9 | 90° C. |
| 12,000 | 20.1 | 120° C. |

### Example 3

Thermal indicating coatings were fabricated from the thermal sensitive materials prepared in Example 2. The coatings were prepared according to the following procedures:

Coating A: Low molecular weight polyethylene (melting point 100° C.)

To 5.0 g of Alberdingk 400N polyurethane (commercially available from Alberdingk-Boley), 1.0 g of zinc salicylate, and 0.5 g of thermal sensitive capsules prepared with low molecular weight polyethylene as the heat-sensitive matrix material were added and mixed for approximately 5 minutes to form a homogenous coating. A wooden substrate was coated with the coating and the coating was allowed to dry. After drying, the coated substrate was exposed to 50° C. for 10 minutes, then 100° C. for 10 minutes. The coating remained clear after exposure to 50° C. but turned pink after exposure to 100° C.

Coating B: High molecular weight polyethylene (melting point 150° C.)

To 5.0 g of Alberdingk 400N polyurethane (commercially available from Alberdingk-Boley), 1.0 g of zinc salicylate, and 0.5 g of thermal sensitive capsules prepared with high molecular weight polyethylene as the heat-sensitive matrix material were added and mixed for approximately 5 minutes to form a homogenous coating. A glass microscope slide was coated with the coating and the coating was allowed to dry. After drying, the coated glass slide was exposed to 100° C. temperature, 150° C., 200° C. and 250° for 10 minutes at each temperature. The coating remained clear after exposure to 100° C. but changed color from clear to pink at 150° C. and above.

Coating C: Cellulose acetate (melting point 250° C.)

To 5.0 g of Alberdingk 400N polyurethane (commercially available from Alberdingk-Boley), 1.0 g of zinc salicylate, and 0.5 g of thermal sensitive capsules prepared with cellulose acetate as the heat-sensitive matrix material were added and mixed for approximately 5 minutes to form a homogenous coating. A glass microscope slide was coated with the coating and the coating was allowed to dry. After drying, the coated glass slide was exposed to 100° C. temperature, 150° C., 200° C. and 250° for 10 minutes at each temperature. The coating remained clear after exposure to temperatures at 100° C., 150° C. and 200° C. but changed color from clear to pink at 250° C.

### Example 4

Thermal indicating appliques were fabricated from the thermal sensitive materials prepared in Example 2. The appliques were prepared according to the following procedures:

Applique A

A 0.004 inch thick sheet of pigmented ethylene chlorotrifluoroethylene applique, such as Fluorogrip E from Integument Technologies Incorporated (Tonawanda, N.Y.), was coated with Coating C of Example 3. After drying, the coated applique was exposed to temperatures of 100° C., 150° C., 200° C., and 250° C. for 10 minutes at each temperature. The coating remained clear after exposures at 100° C., 150° C., and 200° C. but changed color from clear to pink at 250° C.

Applique B

A 0.004 inch thick sheet of clear ethylene chlorotrifluoroethlyene film was coated with a 0.003 inch thick coating of HRJ-14508 from Schenectady International Incorporated (Schenectady, N.Y.), and dried at 50° C. in air in a convection oven. 3.6 g of Upaco SZ-0644A from Worthen Industries, 2.0 g of thermal sensitive capsules prepared with cellulose acetate as the heat-sensitive matrix material, and 0.1 g of Upaco SZ-0644B from Worthen Industries was mixed for 5 minutes on a high shear mixer to produce a homogenous pressure sensitive adhesive (PSA). An applique was formed by applying the PSA at a thickness of 0.004 inches to the top of the dry HRJ-14508 coating. The PSA was allowed to dry at room temperature for 18 hours forming a tacky coating. The tacky coated side of the applique was pressed onto a polymer-matrix composite, rubbing to prevent any air being trapped. The applique was exposed to temperatures of 100° C., 150° C., 200° C., and 250° C. for 10 minutes at each temperature. The coating remained clear after exposures to 100° C., 150° C., and 200° C. but changed from clear to pink at 250° C.

The above description and drawings are only illustrative of preferred embodiments which achieve the objects, features and advantages of the present invention, and it is not intended that the present invention be limited thereto. Any modification of the present invention which comes within the spirit and scope of the following claims is considered part of the present invention.

What is claimed is:

1. A thermal sensitive material comprising at least one indicator dispersed throughout a heat-sensitive matrix material and wherein the thermal sensitive material is impact-resistant.

2. A thermal sensitive material according to claim 1, wherein each indicator is different.

3. A thermal sensitive material according to claim 1, wherein the indicator is a dye.

4. A thermal sensitive material according to claim 3, wherein the dye is a reactive dye.

5. A thermal sensitive material according to claim 4, wherein the reactive dye permanently changes color when exposed to a specific environment.

6. A thermal sensitive material according to claim 5, wherein the specific environment is selected from the group consisting of: a chemical environment, heat, air, visible light, ultraviolet light, black light, ultraviolet radiation, infra-red radiation, microwave radiation, x-ray, water, and acoustic radiation

7. A thermal sensitive material according to claim 4, wherein the specific environment is a chemical environment comprising at least one activator.

8. A thermal sensitive material according to claim 7, wherein the reactive dye is an electron donor and the activator is an electron acceptor.

9. A thermal sensitive material according to claim 4, wherein the reactive dye is selected from the group consisting of: a fluorescent dye; a leuco dye; a pH sensitive dye;
and a metal oxide pigment.

10. A thermal sensitive material according to claim 9, wherein the pH sensitive dye is selected from the group consisting of: quinine, fluorescein, calcein, umbelliferone, stilbene derivatives, an optical brightener, and a fluorescent brightener.

11. A thermal sensitive material according to claim 7, wherein the activator is either an acid having a pKa less than that of the reactive dye or a Lewis acid.

12. A thermal sensitive material according to claim 1, wherein the indicator is at least one activator and wherein the thermal sensitive material is incorporated into a chemical compound having at least one dye.

13. A thermal sensitive material according to claim 1, wherein the heat-sensitive matrix material is either a natural polymer or a synthetic polymer.

14. A thermal sensitive material according to claim 13, wherein the heat-sensitive matrix material is a wax.

15. A thermal sensitive material according to claim 13, wherein the synthetic polymer is selected from the group consisting of: polyethylene; polypropylene; cellulose acetate; polyester; polystyrene; polyamide; polyimide; polycarbonate; polyolefin; fluoropolymer; and polyvinyl chloride.

16. A thermal sensitive material according to claim 1, wherein the heat-sensitive matrix material comprises a polymer blend having a plurality of thermal melting states.

17. A thermal sensitive material according to claim 1, wherein the heat-sensitive matrix changes physical state at temperatures ranging from about 100° C. to about 600° C.

18. A thermal sensitive material according to claim 17, wherein the heat-sensitive matrix material comprises a polymer having a melting point ranging from about 100° C. to about 450° C.

19. A thermal sensitive material according to claim 1, wherein the thermal sensitive material comprises at least one dye material dispersed throughout a first heat-sensitive matrix material forming a core and wherein the core is surrounded by an activator dispersed throughout a second heat-sensitive matrix material.

20. A thermal sensitive material according to claim 19, wherein the first heat-sensitive matrix material is different from the second heat-sensitive matrix material.

21. A thermal sensitive material according to claim 19, wherein the first heat-sensitive matrix material is the same as the second heat-sensitive matrix material.

22. An article prepared from the thermal sensitive material according to claim 1, wherein the article is selected from the group consisting of: a coating; a film; a paint; a decal; an applique; and a shaped article.

23. A thermal sensitive material according to claim 22, wherein the shaped article is selected from the group consisting of: a polymeric container; a circuit board; and an electronic device.

24. A method for detecting thermal exposure of an article, the method comprising the steps of:
a) providing an article prepared from a thermal sensitive material comprising at least one indicator dispersed throughout a heat-sensitive matrix material and wherein the thermal sensitive material is impact-resistant; and
b) examining the article for a color change.
